(19) United States
(12) Patent Application Publication
(10) Pub. No.: US 2008/0226819 A1
(43) Pub. Date: Sep. 18, 2008

(54) METHODS OF MAKING CRYSTALLINE TITANIA COATINGS

(75) Inventors: Luke A. Kutilek, Oakmont, PA (US); Cory D. Steffek, Evanston, IL (US)

Correspondence Address: PPG INDUSTRIES INC;INTELLECTUAL PROPERTY DEPT, ONE PPG PLACE, PITTSBURGH, PA, 15272, US

(73) Assignee: PPG INDUSTRIES OHIO, INC., Cleveland, OH (US)

(21) Appl. No.: 11/952,385

(22) Filed: Dec. 7, 2007

Related U.S. Application Data
(63) Continuation of application No. 10/409,417, filed on Apr. 8, 2003, now abandoned.

(51) Int. Cl. C23C 16/00; C09C 1/36

(52) U.S. Cl. 427/250; 106/436

(57) ABSTRACT

A method is provided for shifting the amorphous to crystalline transition temperature of a titania coating. The method includes adding a dopant, such as Mo, V, Al, Zn, Zr, Li, K, Co, La, Ca, Ba, Si, Ag, Cu, Ni, Mg, Mn, Cd, Fe, Cr, Tb, Y, Sn, Ge, and/or Pd to a titania-containing material. The doped material can then be applied, e.g., by spray pyrolysis, onto a substrate. A coated article is also provided.

### CROSS-REFERENCE TO RELATED APPLICATIONS

This application is a continuation of U.S. application Ser. No. 10/409,417, filed Apr. 8, 2003, which is herein incorporated by reference in its entirety.

### BACKGROUND OF THE INVENTION

1. Field of the Invention

This invention relates generally to metal oxide coatings and, more particularly, to methods of making crystalline titania films, such as by spray pyrolysis or chemical vapor deposition.

2. Technical Considerations

Titania films are incorporated into many different types of coatings. For example, titania films are used as outer protective layers in multi-layer coating stacks to protect less durable coating layers underneath. Titania films can also be utilized for their optical characteristics as a layer within a multi-layer coating stack, such as electromagnetic radiation reflecting layer. In many cases, these titania films are desired to be crystalline to increase the durability of the titania film or to increase photocatalytic activity.

Typically, titania precursor materials are deposited at elevated temperatures, such as in the range of 1200° F. to 1500° F. (648° C. to 800° C.) in order to ensure that the resultant titania film is crystalline. At lower deposition temperatures, such as below about 1150° F. (620° C.), the resultant titania films tend to be amorphous rather than crystalline. Amorphous titania is generally less durable than crystalline titania and, therefore, is not as desirable for many applications.

In one known method, a titania film can be deposited onto a float glass ribbon in a float bath utilizing a chemical vapor deposition (CVD) applicator located in the float bath. The deposition of the titania precursor materials in the float bath ensures the float ribbon is at sufficient temperature (e.g., greater than 1200° F. (648° C.)) to provide a titania coating that is crystalline rather than amorphous. While this known titania deposition method is adequate for obtaining crystalline titania coatings, it does have some drawbacks. For example, for conventional CVD devices, the coating precursor materials must first be heated to sufficient temperature to vaporize the precursor materials. The vapors are then combined at the CVD coating device and directed onto the surface of the float glass ribbon in the float chamber. The vaporization of the precursor materials requires the input of significant energy. Moreover, while this method is adequate for the deposition of crystalline titania films on a float glass ribbon in a float bath, it may not be adequate to obtain crystalline titania films on a substrate outside of the float bath. For example, the temperature of the float glass ribbon exiting a typical float bath is on the order of 1150° F. (620° C.). Deposition of conventional titania precursor materials by CVD at this temperature typically results in titania films that are amorphous or at best poorly crystallized. Therefore, the substrate may have to be reheated to a temperature above about 1200° F. (648° C.) prior to deposition of the precursor materials to ensure a crystalline titania film.

Pyrolytic coating methods, such as conventional spray pyrolysis methods, have some advantages over CVD methods. For example, pyrolytic coating methods are generally less expensive than CVD coating methods. In spray pyrolysis, the coating precursor materials are typically dissolved or suspended in polar solvents to form a precursor solution rather than having to heat the precursor materials to a vapor as is done in CVD methods. These coating precursor solutions for spray pyrolysis are easier to prepare than the vaporized materials required by CVD. Moreover, pyrolytic coating methods can utilize materials that would be unstable in the vapor phase, e.g., materials that would decompose if heated to sufficient temperatures to vaporize the materials. Additionally, spray pyrolysis can be performed at much lower temperatures than conventional CVD coating methods. For example, spray pyrolysis coating methods can be performed on a glass substrate outside of the float bath at a temperature of less than about 1150° F. (620° C.).

However, while spray pyrolysis does provide advantages of lower coating temperature, wider selection of coating materials, and more economical coating precursors, it does have some drawbacks when forming titania coatings. For example, aqueous spray pyrolysis cannot be practiced in a conventional float bath due to the high temperatures and reducing atmosphere of the float bath interior. Therefore, pyrolytic coating methods must be practiced outside of the float bath. However, pyrolytically deposited titania coatings formed on float glass ribbons outside of the float bath using conventional high amorphous to crystalline transition temperature materials tend to be amorphous or poorly crystallized due to the lower deposition temperatures involved and, therefore, are not as durable as the crystalline titania films formed by CVD coating methods inside the float bath. One method of trying to alleviate this problem is by first forming a titania film by spray pyrolysis outside of the float bath and then post-heating the coated article to elevated temperatures to convert the titania film from substantially amorphous to substantially crystalline. However, this method requires an additional heating step which can increase the cost of the process as well as the time required to form the coating.

Therefore, it would be advantageous to provide a method of making crystalline or substantially crystalline titania coatings by spray pyrolysis but at temperatures lower than that of conventional coating methods.

### SUMMARY OF THE INVENTION

A method is provided for shifting the amorphous to crystalline transition temperature of a titania coating material. The method comprises adding at least one dopant, such as but not limited to Mo, V, Al, Zn, Zr, Li, K, Co, La, Ca, Ba, Si, Ag, Cu, Ni, Mg, Mn, Cd, Fe, Cr, Tb, Y, Sn, Ge, and/or Pd and/or mixtures or combinations thereof to a titania-containing material to decrease the amorphous to crystalline transition temperature of the material. The doped titania material can be applied onto a substrate, such as but not limited to by pyrolytic deposition or CVD, at temperatures lower than conventional deposition temperatures and still results in a crystalline or substantially crystalline titania film.

A coated article is also provided. The article comprises a substrate and a doped titania coating deposited over at least a portion of the substrate. The dopant can be selected from one or more of Mo, V, Al, Zn, Zr, Li, K, Co, La, Ca, Ba, Si, Ag, Cu, Ni, Mg, Mn, Cd, Fe, Cr, Tb, Y, Sn, Ge, and/or Pd and/or mixtures or combinations thereof. The coating can be crystalline or substantially crystalline and can have a grain size of greater than or equal to 30 nanometers (nm), such as greater or equal to than 60 nm, such as greater than or equal to 80 nm, such as in the range of 30 nm to 200 nm, such as in the range of 60 nm to 160 nm, such as in the range of 80 nm to 140 nm, such as having an average grain size of 120 nm. The coating can be photohydrophilic or photocatalytic or both. The coating can have a crystalline structure comprising a monoclinic space group.

A pigment of the invention comprises a vanadium doped titania material having a crystal lattice comprising a monoclinic space group.

### DESCRIPTION OF THE DRAWING

FIG. 1 is a side, sectional view (not to scale) of a portion of a substrate having a coating incorporating features of the invention;

FIG. 2 is a graph of count intensity versus theta value for titania films doped with differing amounts of vanadium (atomic % V);

FIG. 3 is a graph of count intensity versus theta value for a vanadium doped titania coating deposited at differing deposition temperatures;

FIG. 4 is a graph of count intensity versus theta value for vanadium doped titania films pyrolytically deposited on a 1150° F. (620° C.) substrate and subsequently post-heated to 900° F. (482° C.) for 30 minutes;

FIG. 5 is a graph of X-ray fluorescence intensity versus amount of vanadium for various vanadium doped titania films; and

FIG. 6 shows graphs of count intensity versus theta value for a vanadium doped titania film from FIG. 1 overlayed with the predicted pattern for a crystal structure having a monoclinic space group C2/m crystal system (FIG. 6A) and the predicted pattern for an anatase crystal system (tetragonal space group IR₁/amd) (FIG. 6B).

### DESCRIPTION OF THE PREFERRED EMBODIMENTS

As used herein, spatial or directional terms, such as “left”, “right”, “inner”, “outer”, “above”, “below”, “top”, “bottom”, and the like, relate to the invention as it is shown in the drawing figures. However, it is to be understood that the invention may assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims are approximations that may vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to include the beginning and ending range values and to encompass any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 5.5 to 10. Further, as used herein, the terms “deposited over”, “applied over”, or “formed over” mean deposited or formed on but not necessarily in contact with the surface. For example, a coating composition “deposited over” a substrate does not preclude the presence of one or more other coating films of the same or different composition located between the deposited coating and the substrate. The term “film” refers to a region of a coating having a desired or selected composition. A “layer” comprises one or more “films”. A “coating” or “coating stack” is comprised of one or more “layers”. Any document referred to herein should be considered to be “incorporated by reference” in its entirety. All x-ray diffraction data and grain size (including average grain size) values reported herein are those determined using a conventional Panalytical “X-Pert” x-ray diffraction instrument (step size 0.02 theta, step time 1 second, range 15-85 2theta, with a fixed theta of 0.5, run at 40 kV, 50 mA) using conventional PC-APD X-Manager software.

An exemplary article having a doped titania coating in accordance with the invention will first be described and then a method of making the article will be described. However, it is to be understood that the exemplary article and exemplary method are provided simply to describe the general concepts of the invention but the invention is not limited to the particularly described exemplary embodiments.

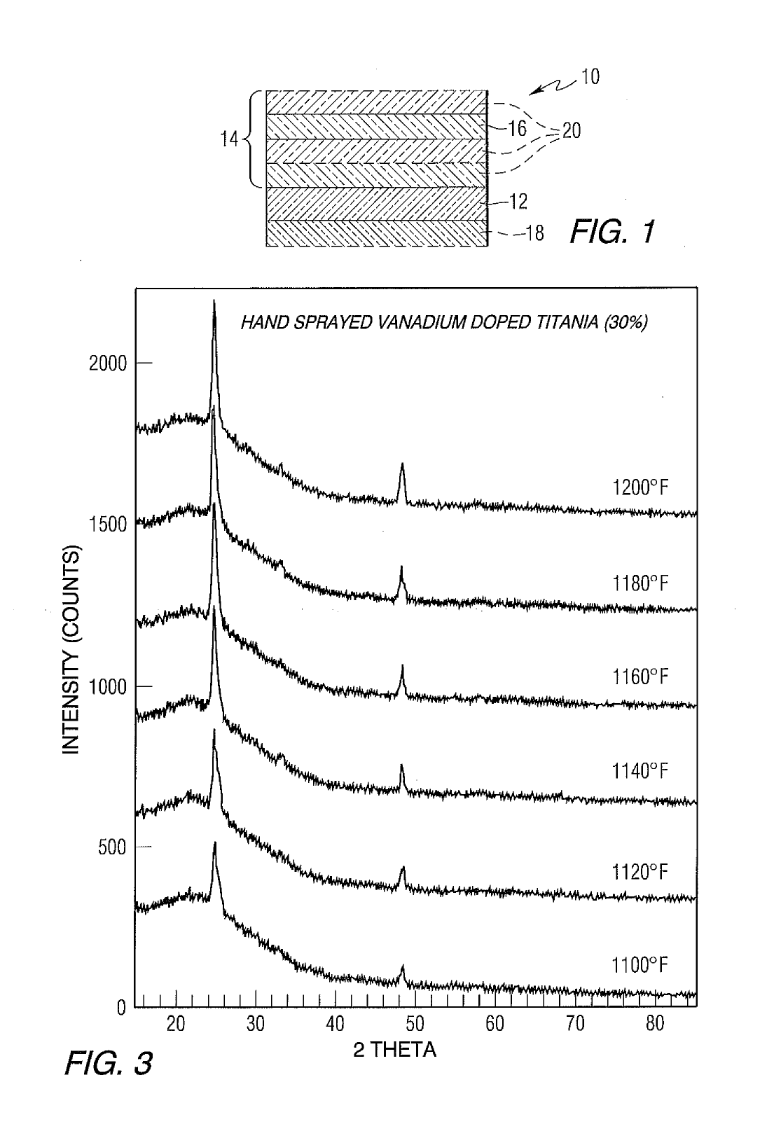

FIG. 1 illustrates an exemplary article 10 having a substrate 12 with a coating stack 14 deposited over at least a portion of the substrate 12. The coating stack 14 can include a modified titania (“MT”) coating layer 16 as described below. The MT layer 16 can be formed or deposited directly on the substrate 12 or, as shown in FIG. 1, can be incorporated as one layer of a multi-layer coating stack 14 having one or more other layers 20. For example, the MT layer 16 can be a protective or outer layer or, as shown in FIG. 1, can be an under layer in the coating stack 14. As used herein, the term “outer layer” refers to the outermost layer of the coating stack 14, e.g., the coating layer farthest from the substrate 12. The term “under layer” refers to a coating region or layer located between the substrate 12 and a subsequently applied “outer layer”. In one embodiment, a functional coating 18 can optionally be deposited over at least a portion of the substrate 12.

The substrate 12 is not limiting to the invention and can be of any desired material having any desired characteristics, such as opaque, translucent, or transparent to visible light. By “transparent” is meant having a transmittance through the substrate of greater than 0% up to 100%. By “visible light” or “visible region” is meant electromagnetic energy in the range of 395 nanometers (nm) to 800 nm. Alternatively, the substrate can be translucent or opaque. By “translucent” is meant allowing electromagnetic energy (e.g., visible light) to pass through the substrate but diffusing this energy such that objects on the side of the substrate opposite to the viewer are not clearly visible. By “opaque” is meant having a visible light transmittance of 0%. Examples of suitable substrates include, but are not limited to, plastic substrates (such as acrylic polymers, such as polyacrylates; polyalkylmethacrylates, such as polymethylmethacrylates, polyethylmethacrylates, polypropylmethacrylates, and the like; polyurethanes; polycarbonates; polyalkylterephthalates, such as polyethyleneterephthalate (PET), polypropyleneterephthalates, polybutyleneterephthalates, and the like; polysiloxane-containing polymers; or copolymers of any monomers for preparing these, or any mixtures thereof); metal substrates, such as but not limited to galvanized steel, stainless steel, and aluminum; ceramic substrates; tile substrates; glass substrates; or mixtures or combinations of any of the above. For example, the substrate can be conventional untinted soda-lime-silica glass, i.e., “clear glass”, or can be tinted or otherwise colored glass, borosilicate glass, leaded glass, tempered, untempered, annealed, or heat-strengthened glass. The glass may be of any type, such as conventional float glass or flat glass, and may be of any composition having any optical properties, e.g., any value of visible radiation transmission, ultraviolet radiation transmission, infrared radiation transmission, and/or total solar energy transmission. Types of glass suitable for the practice of the invention are described, for example but not to be considered as limiting, in U.S. Pat. Nos. 4,746,347; 4,792,536; 5,240,886; 5,385,872; and 5,393,593.

The modified titania (“MT”) coating layer 16 can be formed or deposited over at least a portion of the substrate 12 in any conventional manner. As used herein, the term “modified titania” refers to a titania-containing material or coating that includes at least one additive or dopant that acts to shift, e.g., decrease, the amorphous to crystalline transition temperature of the titania-containing material over that of the same material without the additive or dopant. The terms “amorphous to crystalline transition temperature” or “transition temperature” mean the temperature or range of temperatures over which the titania material or coating shifts from amorphous or substantially amorphous to crystalline or substantially crystalline. By “substantially amorphous” is meant that no reflections to indicate the presence of a crystalline structure are observed in the x-ray diffraction pattern and there is no observable grain size (utilizing the conditions referred to in paragraph 16). By “substantially crystalline” is meant that reflections in the x-ray diffraction pattern are present to indicate a crystalline structure (such as but not limited to a crystalline structure having an average grain size greater than 80 nm). The crystalline structure can include one or more of anatase, rutile, brookite, or monoclinic crystalline structures.

In one embodiment, the MT coating layer 16 can be photoactive. As used herein, the terms “photoactive” or “photoactively” refer to the photogeneration of a hole-electron pair when the MT coating layer 16 is illuminated by radiation within the photoabsorption band of the coating material. For example, the MT layer 16 can be photoactive when illuminated by one or more wavelengths of ultraviolet (“UV”) radiation. By “UV radiation” is meant electromagnetic radiation having wavelengths in the range of 10 nm to less than 395 nm. By “photoabsorption band” is meant the wavelength or range of wavelengths of electromagnetic radiation absorbed by a material to render the material photoactive. For example, the MT coating 16 can be photocatalytic and/or photohydrophilic or both. By “photocatalytic” is meant a coating having self-cleaning properties, i.e., a coating which upon exposure to electromagnetic radiation in the photoabsorption band of the material interacts with organic contaminants on the coating surface to degrade or decompose the organic contaminants. By “photohydrophilic” or “photoactively hydrophilic” is meant a coating on which the contact angle of a water droplet decreases with time as a result of exposure of the coating to electromagnetic radiation in the photoabsorption band of the material. For example, the contact angle can decrease to a value less than 15°, such as less than 10°, and can become superhydrophilic, e.g., decrease to less than 5°, after sixty minutes of exposure to radiation in the photoabsorption band of the material having an intensity of 28 W/m² at the coating surface. Although photoactive, the MT coating 16 may not necessarily be photocatalytic to the extent that it is self-cleaning, i.e., may not be sufficiently photocatalytic to decompose organic materials like grime on the coating surface in a reasonable or economically useful period of time.

The MT coating layer 16 of the invention includes (1) a titania-containing coating material and (2) an additive or dopant configured to shift, e.g., decrease, the amorphous to crystalline transition temperature of the coating material (1) compared to the coating material (1) without the dopant (2).

The titania coating material (1) can include titanium oxides or titanium oxide precursors. In one embodiment, the material (1) can also include one or more other metal oxides or precursors, such as but not limited to, one or more metal oxides or semiconductor metal oxides, such as but not limited to silicon oxides, molybdenum oxides, vanadium oxides, aluminum oxides, iron oxides, silver oxides, cobalt oxides, chromium oxides, copper oxides, tungsten oxides, zinc oxides, zinc/tin oxides, strontium titanate and/or mixtures thereof. The metal oxides can include oxides, super-oxides or sub-oxides of the metal, e.g., of titania.

The MT coating 16 can be crystalline or at least partially crystalline. By “at least partially crystalline” is meant that the MT coating 16 can include both amorphous and crystalline structures. Titanium oxides exist in an amorphous form and four crystalline forms, i.e., the anatase (tetragonal space group IR₁/amd), rutile (tetragonal space group P4₂/mnm), brookite (orthorhombic space group Pbca), and monoclinic (monoclinic phase space group C2/m) crystalline forms. The crystalline lattice of the MT coating 16 can include one or more of these crystalline forms.

The dopant (2) can be any material that acts to shift, e.g., decrease, the amorphous to crystalline transition temperature of the titania material (1) over that of the titania material (1) without the dopant (2). For example, in one embodiment, the dopant (2) can be selected from one or more of lithium (Li), zirconium (Zr), potassium (K), cobalt (Co), lanthanum (La), aluminum (Al), calcium (Ca), barium (Ba), silicon (Si), silver (Ag), zinc (Zn), copper (Cu), nickel (Ni), magnesium (Mg), manganese (Mn), cadmium (Cd), iron (Fe), chromium (Cr), terbium (Tb), yttrium (Y), tin (Sn), vanadium (V), germanium (Ge), molybdenum (Mo), and palladium (Pd), and/or mixtures or combinations thereof.

The dopant (2) can be present in any amount to achieve a desired shift in the amorphous to crystalline transition temperature of the titania material (1). For example, with aluminum and molybdenum dopants, the dopant (2) can be present in an amount less than 5 atomic percent, such as less than 3 atomic percent, such as less than 2 atomic percent, such as in the range of greater than 0 atomic percent to less than 2 atomic percent based on the composition of the resultant coating. For other dopants, such as vanadium, the dopant can be present in an amount less than 10 atomic percent, such as less than 8 atomic percent, such as less than or equal to 6 atomic percent, such as in the range of 0 atomic percent to 8 atomic percent, such as in the range of 1 atomic percent to 6 atomic percent.

The MT coating 16 can have any desired thickness. In one exemplary embodiment, the MT coating 16 can have a thickness less than 1000 Å, such as less than 800 Å, such as less than 600 Å, such as in the range of greater than 0 Å to 600 Å, such as in the range of 200 Å to 500 Å.

The MT coating 16 can have a grain size greater than or equal to 30 nm, such as greater than or equal to 60 nm, such as greater than or equal to 80 nm. In one embodiment, the grain size of the MT coating 16 can be in the range of 30 nm to 200 nm, such as greater than 60 nm to 160 nm, such as in the range of 80 nm to 140 nm, such as having an average grain size of 120 nm. As used herein, the terms “grain size” or “average grain size” refers to the grain size (or the average of a plurality of grain size measurements) determined by extrapolation of x-ray diffraction (XRD) data using a conventional PC-APD X-manager program commercially available from Panalytical Corp.

The MT coating 16 can be deposited directly on, i.e., in surface contact with, the substrate 12. Alternatively, as shown in FIG. 1, one or more other layers or films 20 (shown by dashed lines) may be interposed between the MT coating 16 and the substrate 12.

As shown in FIG. 1, in addition to the MT coating 16 of the invention, one or more functional coatings 18 can be deposited on or over the substrate 12. For example, a functional coating 18 can be deposited over a major surface of the substrate 12 that is opposite the surface on which the MT coating 16 is deposited. As used herein, the term “functional coating” refers to a coating which modifies one or more physical properties of the substrate on which it is deposited, e.g., optical, thermal, chemical or mechanical properties, and is not intended to be removed from the substrate during subsequent processing. The functional coating 18 can have one or more functional coating films of the same or different composition or functionality. The film may be homogeneous, non-homogeneous, or have a graded compositional change. A film is “homogeneous” when the outer surface or portion (i.e., the surface or portion farthest from the substrate), the inner surface or portion (i.e., the surface or portion closest to the substrate) and the portion between the outer and inner surfaces have substantially the same composition. A film is “graded” when the film has a substantially increasing fraction of one or more components and a substantially decreasing fraction of one or more other components when moving from the inner surface to the outer surface or vice versa. A film is “non-homogeneous” when the film is other than homogeneous or graded. A “coating” is composed of one or more “films”.

The functional coating 18 can be an electrically conductive coating, such as, for example, an electrically conductive heated window coating as disclosed in U.S. Pat. Nos. 5,653,903 and 5,028,759, or a single-film or multi-film coating capable of functioning as an antenna. Likewise, the functional coating 18 can be a solar control coating, for example, a visible, infrared or ultraviolet energy reflecting or absorbing coating. Examples of suitable solar control coatings are found, for example, in U.S. Pat. Nos. 4,898,789; 5,821,001; 4,716,086; 4,610,771; 4,902,580; 4,716,086; 4,806,220; 4,898,790; 4,834,857; 4,948,677; 5,059,295; and 5,028,759, and also in U.S. patent application Ser. No. 09/058,440. Similarly, the functional coating 18 can be a low emissivity coating. “Low emissivity coatings” allow visible wavelength energy, e.g., 395 nm to about 800 nm (e.g., to about 780 nm), to be transmitted through the coating but reflect longer-wavelength solar infrared energy and/or thermal infrared energy and are typically intended to improve the thermal insulating properties of architectural glazings. By “low emissivity” is meant emissivity less than 0.4, such as less than 0.3, such as less than 0.2. Examples of low emissivity coatings are found, for example, in U.S. Pat. Nos. 4,952,423 and 4,504,109 and British reference GB 2,302,102. The functional coating 18 can be a single layer or multiple layer coating and can comprise one or more metals, non-metals, semi-metals, semiconductors, and/or alloys, compounds, composites, combinations, or blends thereof. For example, the functional coating 18 can be a single layer metal oxide coating, a multiple layer metal oxide coating, a non-metal oxide coating, or a multiple layer coating.

Examples of suitable functional coatings for use with the invention are commercially available from PPG Industries, Inc. of Pittsburgh, Pa. under the SUNGATE® and SOLARBAN® families of coatings. Such functional coatings typically include one or more anti-reflective coating films comprising dielectric or anti-reflective materials, such as metal oxides or oxides of metal alloys, which can be transparent or substantially transparent to visible light. The functional coating 18 can also include infrared reflective films comprising a reflective metal, e.g., a noble metal such as gold, copper or silver, or combinations or alloys thereof, and can further comprise a primer film or barrier film, such as titanium, as is known in the art, located over and/or under the metal reflective layer.

The MT coating 16 can be formed over the substrate 12 in any conventional manner, such as but not limited to magnetron sputter vapor deposition (MSVD), chemical vapor deposition (CVD), spray pyrolysis (i.e., pyrolytic deposition), and wet chemical deposition (e.g., sol-gel), just to name a few. In the spray pyrolysis method, for example, an organic or metal-containing precursor composition having (1) a metal oxide precursor material including a titania precursor material, and (2) at least one dopant as described above, can be carried in an aqueous suspension, e.g., an aqueous solution, and directed toward a surface of the substrate 12 while the substrate 12 is at a deposition temperature high enough to cause the precursor composition to decompose and form the MT coating 16 on the substrate 12. By “deposition temperature” is meant the temperature of the substrate at the time of deposition of a coating precursor material. In one exemplary embodiment, the substrate can be at a temperature of less than 1200° F. (648° C.) for pyrolytic deposition of the MT coating 16. For example, the substrate can be at a temperature in the range of less than 1115° F. (601° C.), such as less than 1100° F. (593° C.), such as less than 500° F. (260@ C), such as in the range of 400° F. to 1200° F. (204° C. to 648° C.), such as in the range of 1100° F. to 1150° F. (593° C. to 620° C.). In the practice of the invention, the presence of the dopant provides that the pyrolytically deposited MT coating 16 is crystalline or substantially crystalline upon pyrolytic deposition even at temperatures below those normally required to achieve crystalline titania coatings. As a general rule, the amount of crystallinity of the MT coating 16 increases with increasing deposition temperature.

In one particular pyrolytic deposition method, a vanadium-containing precursor material, such as vanadyl acetylacetonate in a polar solvent, such as N,N-dimethylformamide, can be combined with a titania precursor material, such as titanyl acetylacetonate in water. The amount of the vanadium precursor material can be selected to provide a desired ratio of vanadium to titania in a final coating. For example, the vanadium precursor material can be selected such that the resultant MT coating includes about 1 atomic percent to about 8 atomic percent, such as 1 atomic percent to 6 atomic percent, vanadium. The precursor solutions or suspensions can be sprayed onto a substrate, such as a glass substrate, at a temperature sufficient to pyrolyze the precursor materials and form the MT coating 16. In one non-limiting embodiment, the substrate can be at a temperature of less than 1200° F. (648° C.), such as less than 1120° F. (604° C.), such as less than 1100° F. (593° C.), such as less than 1050° F. (565° C.), such as in the range of 400° F. to 1100° F. (204° C. to 593° C.), such as in the range of 1100° F. to 1130° F. (593° C. to 609° C.). For a vanadium doped titania coating pyrolytically deposited at a deposition temperature in the range of about 1100° F. to 1200° F. (593° C. to 648° C.) and with the vanadium in a range of 1 atomic percent to 8 atomic percent, the resultant MT coating has been found to be crystalline or substantially crystalline. With the vanadium in the range of about 5 atomic percent to about 7 atomic percent, the crystalline structure has been determined to be monoclinic or substantially monoclinic (i.e., the crystal lattice comprises a monoclinic crystal system). By “substantially monoclinic” is meant that of the crystalline coating structure is predominately monoclinic, such as having at least 50 wt. %, such as greater than 60 wt. %, such as greater than 70 wt. %, such as greater than 80 wt. %, such as greater than 90 wt. %, is in the monoclinic crystalline phase. The coating can also include other crystalline phases, such as anatase (tetragonal crystal system) in addition to the monoclinic phase (monoclinic crystal system). However, upon post-deposition heat treatment of a coating to a temperature of about 900° F. (482° C.) for about 30 minutes, the resultant coating can include both monoclinic and anatase crystalline forms, with the coating being predominately anatase. While the vanadium doped titania coating is predominately in the monoclinic phase it is not photocatalytic, it is photohydrophilic when exposed to UV radiation. The anatase phase vanadium doped titania can be photocatalytic and/or photohydrophilic.

In another exemplary embodiment, an aluminum or molybdenum precursor material, such as aluminum acetylacetonate and molybdenum acetylacetonate can be mixed with a titania precursor material and deposited by spray pyrolysis on a substrate at a temperature in the range of about 1000° F. to 1150° F. (537° C. to 620° C.). With the amount of aluminum or molybdenum present to provide a coating having greater than 0 up to 2 atomic percent Al or Mo, the coating deposited is in the amorphous phase. However, when the coating is heated to a temperature of about 900° F. (482° C.) for about 30 minutes, the coating becomes anatase or substantially anatase.

In addition to coating substrates, the invention can find use in other areas. For example, known crystalline titania-containing pigments useful in paints and other polymeric coating materials can be photocatalytic and, therefore, must be coated with a protective coating to prevent the titania pigments from chalking the paint. By “chalking” is meant that the paint eventually becomes brittle and flaky due to the photocatalytic effect of the titania pigments, particularly titania pigments in the anatase phase. However, in the practice of the invention, vanadium doped titania coatings can be deposited on a substrate by spray pyrolysis to selectively form the monoclinic crystalline phase of titania as described above. Since the monoclinic phase is not photocatalytic, the resultant vanadium doped titania particles or pigments should not lead to the chalking problem of prior titania pigments.

Illustrating the invention are the following Examples which, however, are not to be considered as limiting the invention to their details.

### Example 1

This Example illustrates the effect of vanadium on the crystallinity of a resultant vanadium doped titania coating.

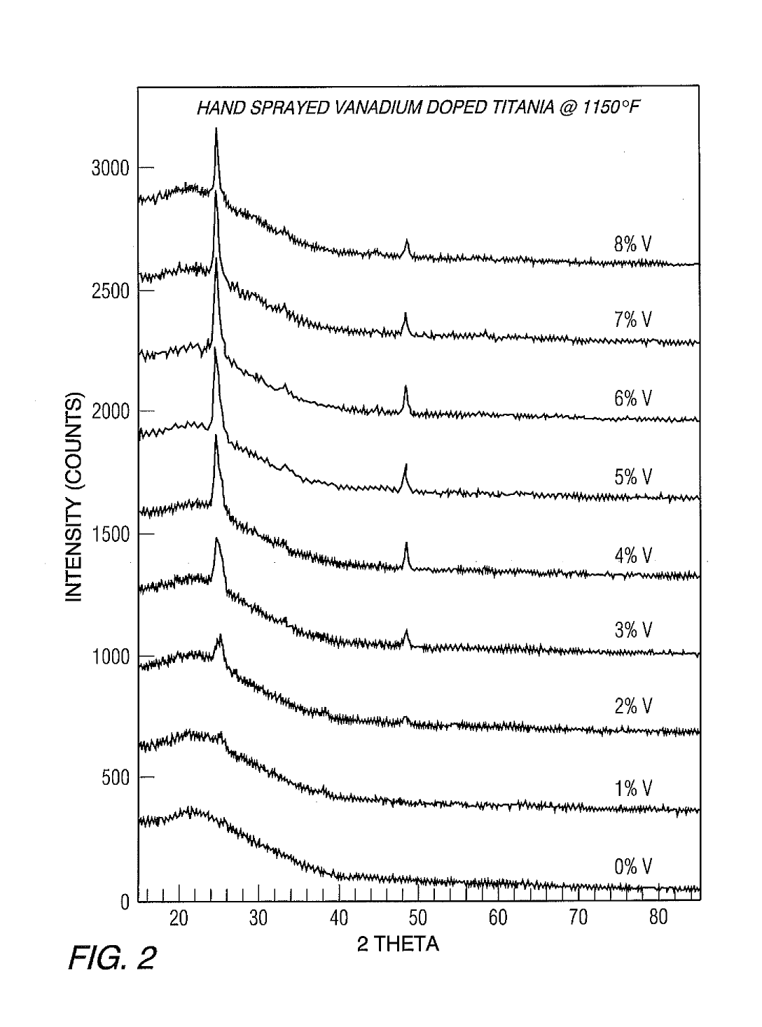

A solution of 5 wt. % vanadyl acetylacetonate in N,N-dimethylformamide was combined with a suspension of 20 wt. % titanyl acetylacetonate in water in various amounts to form vanadium containing titania precursor compositions. The precursor compositions were sprayed onto clear float glass coupons which had been heated in a 1150° F. (620° C.) furnace for 8 minutes. The resultant coatings were analyzed by X-ray diffraction using a commercially available Panalytical “X-Pert” X-ray diffraction instrument (step size 0.04 theta, step time 1 second, range 15-85 2theta, with a fixed theta of 0.5, run at 40 kV, 50 mA). The results of this analysis are shown in FIG. 2 for precursor compositions containing 0 volume percent of the 5 wt. % vanadyl acetylacetonate solution to 40 volume percent of the vanadyl solution (i.e., 0 atomic % V to 8 atomic % V). It is estimated that 5 vol. % of the vanadyl solution corresponds to about 1 atomic percent vanadium in the resultant doped titania coating. At 0 vol. % vanadyl acetylacetonate (i.e., titania alone), no crystallinity was observed. From greater than 5 vol. % vanadyl acetylacetonate solution (about 1 atomic percent vanadium) until about 35 vol. % vanadyl acetylacetonate solution (about 7 atomic percent vanadium), the crystallinity of the resultant coating increased as evidenced by increasing count intensity at about 25 theta. However, above about 35 vol. % vanadyl acetylacetonate solution, the crystallinity of the coating began to decrease.

### Example 2

This Example illustrates the effect of deposition temperature on the crystallinity of a vanadium doped titania coating.

Since the 30 vol. % vanadyl acetylacetonate solution in Example 1 (about 6 atomic percent vanadium) provided significant crystallinity, this composition was chosen to test the effect of deposition temperature on crystallinity. 30 vol. % of the 5 wt. % vanadyl acetylacetonate solution was mixed with a 20 wt. % titanyl acetylacetonate suspension and was spray applied onto clear float glass coupons at varying temperatures from 1100° F. to 1200° F. (593° C. to 648° C.). The resultant coatings were analyzed by X-ray diffraction and the results are shown in FIG. 3. As can be seen, even at temperatures as low as 1100° F. (593° C.), the resultant vanadium doped titania coatings showed crystallinity.

### Example 3

This Example illustrates the effect of post-heat treatment on vanadium doped titania coatings.

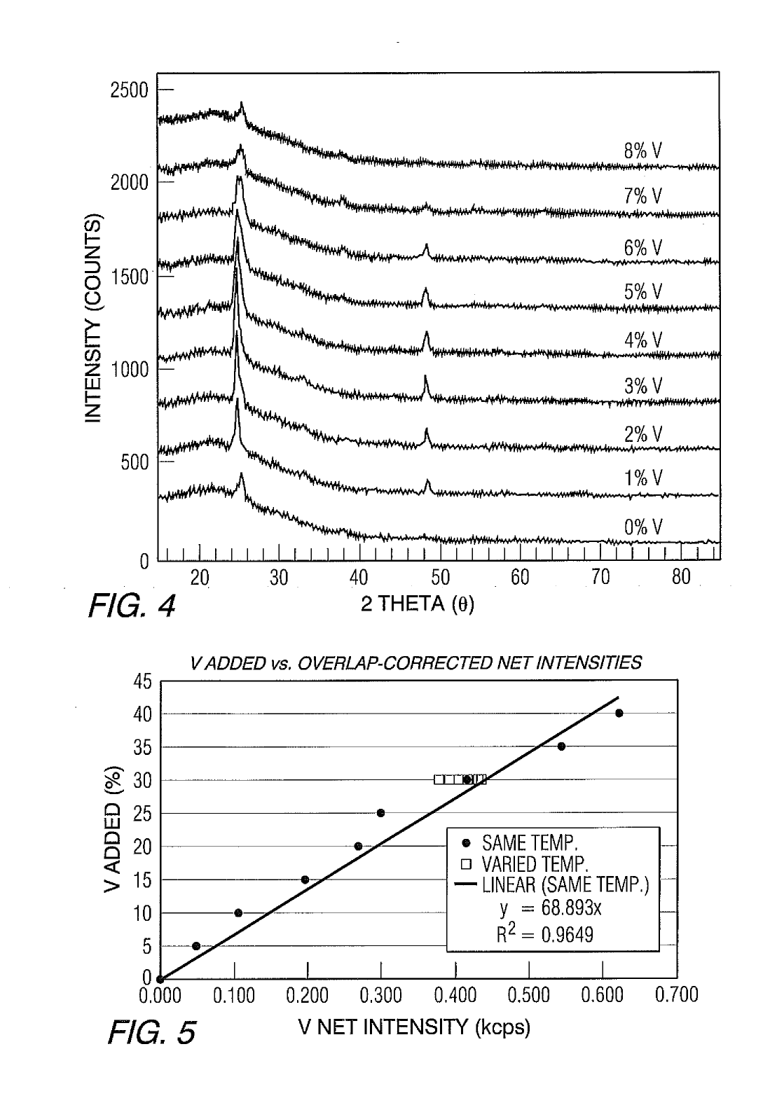

Varying volume percents of the 5 wt. % vanadyl solution were mixed with the 20 wt. % titanyl suspension. The resultant mixtures were sprayed onto clear float glass coupons which had been soaked in a 1150° F. (620° C.) furnace for 8 minutes in similar manner to Example 1. After cooling, the samples were placed in a furnace and heated to a temperature of 900° F. (482° C.) for 30 minutes and then slowly cooled over an hour. The resultant coatings were analyzed by X-ray diffraction and the results are shown in FIG. 4. The solutions with 5 vol. % to 20 vol. % vanadyl acetylacetonate solution (1 atomic % V to 4 atomic % V) became more crystalline than the similarly deposited coatings from Example 1 (as evidenced by the higher peaks at about 25 theta and as also evidenced by the larger grain size (about 120 nm)). However, at 25 vol. % vanadium acetylacetonate solution (5 atomic % V), the apparent peak at about 25 theta split into (110) monoclinic and (101) anatase crystallinity. Concentrations above 25 vol. % vanadium acetylacetonate solution (5 atomic % V) showed predominantly anatase crystallinity. The presence of anatase or monoclinic diffraction patterns was determined using the ICDD database through PC-ADP X-manager, a conventional Powder Diffraction software commercially available from Panalytical Corp.

### Example 4

FIG. 5 shows x-ray fluorescence data versus amount of vanadium added. Specifically, FIG. 5 shows the volume % of the 5 wt. % vanadyl solution added versus the vanadium net peak intensity. The data indicates a linear relationship for vanadium doped titania coatings deposited at 1150° F. (620° C.).

### Example 6

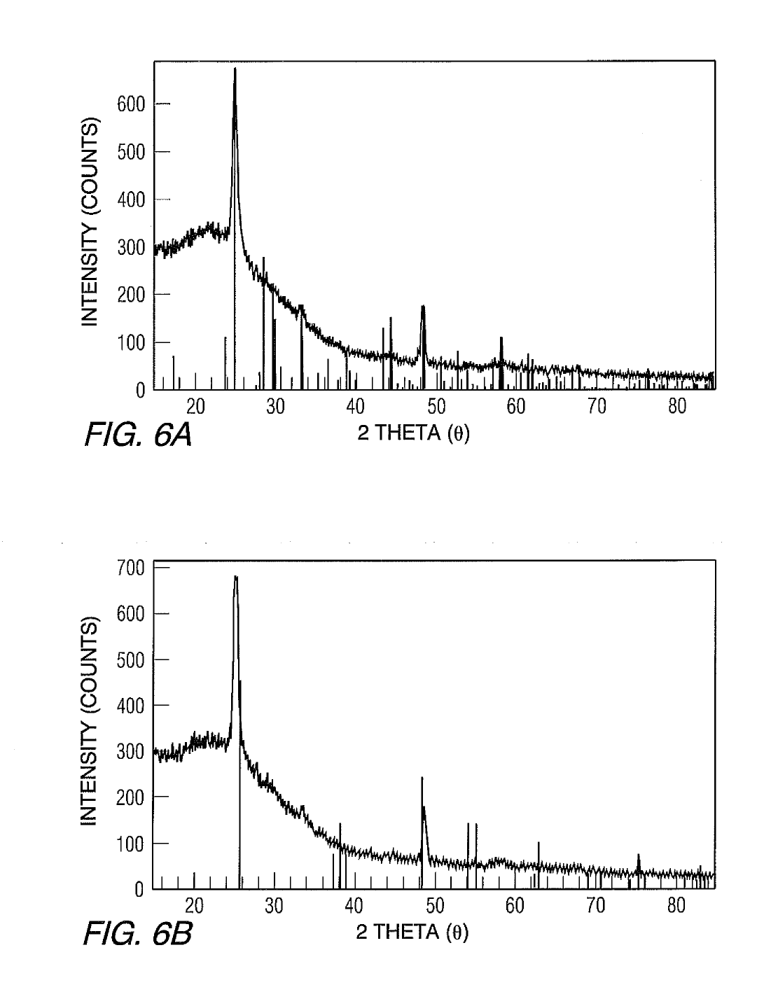

FIG. 6 shows the X-ray diffraction results from Example 1 for the coating made with the 30 vol. % vanadyl solution overlayed with the predicted patterns for monoclinic titania (space group (C2/m)) (FIG. 6A) and anatase titania (tetragonal space group I4₁/amd) (FIG. 6B) as available from the commercially available Powder Diffraction software. As can be seen, the crystallinity is shown to be monoclinic.

It will be readily appreciated by those skilled in the art that modifications may be made to the invention without departing from the concepts disclosed in the foregoing description. Accordingly, the particular embodiments described in detail herein are illustrative only and are not limiting to the scope of the invention, which is to be given the full breadth of the appended claims and any and all equivalents thereof.

1-25. (canceled)

26. A method of making a crystalline titania coating on a glass substrate by aqueous spray pyrolysis without post-heating, comprising the steps of:
providing a glass substrate having a temperature less than or equal to 1100° F.;
directing an aqueous coating composition toward the glass substrate, the coating composition comprising a titania precursor material and at least one dopant selected from at least one of Mo, V, Al, Zn, Zr, Li, K, Co, La, Ca, Ba, Si, Ag, Cu, Ni, Mg, Mn, Cd, Fe, Cr, Tb, Y, Sn, Ge, and Pd, and mixtures or combinations thereof, wherein the dopant is present in an amount less than 10 atomic percent, and
wherein the coating composition pyrolyzes on the substrate to form the crystalline titania coating without subsequent post-heating.

27. The method of claim 26, wherein the dopant is vanadium and is present in an amount of 1 to 6 atomic percent.

28. The method of claim 26, wherein the dopant is aluminum and is present in an amount of less than 2 atomic percent.

29. The method of claim 26, wherein the dopant is molybdenum and is present in an amount of less than 2 atomic percent.

30. The method of claim 26, wherein the precursor material and dopant are applied at a temperature in the range of 400° F. to 1100° F. (204° C. to 593° C.).

31. The method of claim 26, wherein the dopant is vanadium, wherein the vanadium is present in an amount of 1 to 8 atomic percent, and wherein the coating includes a crystal lattice comprising a monoclinic crystal system.

32. The method of claim 26, wherein the vanadium is present in an amount of 5 to 7 atomic percent and the coating includes monoclinic and tetragonal (anatase) crystal systems.

33. The method of claim 26, wherein the coating is photoactive

34. The method of claim 26, wherein the coating is photohydrophilic.

35. A pigment, comprising:
a vanadium doped titania material having a crystalline structure comprising a monoclinic crystal system.

36. The pigment of claim 35, wherein the vanadium is present in the range of 1 atomic percent to 8 atomic percent of the titania material.

37. The pigment of claim 35, wherein the vanadium is present in the range of 5 atomic percent to 7 atomic percent of the titania material.
